(19) United States
(12) Patent Application Publication
(10) Pub. No.: US 2022/0319884 A1
(43) Pub. Date: Oct. 6, 2022

(54) TEMPERATURE CALIBRATION SHEETS AND APPLICATION METHODS THEREOF

(71) Applicant: CHANGXIN MEMORY TECHNOLOGIES, INC., Hefei City, Anhui (CN)

(72) Inventor: ShihChieh LIN, Hefei (CN)

(73) Assignee: CHANGXIN MEMORY TECHNOLOGIES, INC., Hefei City, Anhui (CN)

(21) Appl. No.: 17/310,763

(22) PCT Filed: Mar. 10, 2021
(86) PCT No.: PCT/CN2021/079969

§ 371 Date: Aug. 21, 2021

(30) Foreign Application Priority Data
Mar. 19, 2020 (CN) 202010195361.1

(51) Int. Cl. H01L 21/67; G01K 15/00; G01K 7/00

(52) U.S. Cl. CPC H01L 21/67248; G01K 15/002; G01K 7/00

(57) ABSTRACT

A temperature calibration sheet includes a main body and a plurality of test keys arranged in the main body. The test keys have voltage-temperature characteristic curves corresponding to a set current. Temperatures of the test keys are obtained by detecting voltages of the test keys. The temperature calibration sheet can simulate a state of a wafer, sidewalls of the test keys are not exposed to the air, and the state of the temperature calibration sheet arranged on a semiconductor machine is the same as that of the wafer arranged on the semiconductor machine, such that the temperature of the temperature calibration sheet can truly reflect the temperature of the wafer when arranged on the semiconductor machine, and the temperature of the semiconductor machine can be calibrated accurately.

### CROSS-REFERENCE TO RELATED APPLICATIONS

The present disclosure claims priority to Chinese Patent Application No. 202010195361.1, entitled “TEMPERATURE CALIBRATION SHEETS AND APPLICATION METHODS THEREOF”, filed on Mar. 19, 2020, which is incorporated herein by reference in its entirety.

### TECHNICAL FIELD

The present disclosure relates to the field of semiconductor manufacturing, and in particular to a temperature calibration sheet and an application method thereof.

### BACKGROUND

In the semiconductor manufacturing process, it is usually necessary to perform high-temperature or low-temperature processes on a semiconductor machine. The temperature has a great influence on the semiconductor manufacturing process. Particularly for temperature-sensitive processes, the influence from temperature is not ignorable. Therefore, it is very important to calibrate the temperature of the machine.

Existing temperature calibration methods for a semiconductor machine are to place one or more temperature calibrators on the semiconductor machine to calibrate the temperature of the semiconductor machine, so as to ensure that the temperature of the semiconductor machine reaches a set temperature and the wafer has a consistent temperature in various parts of the semiconductor machine. The existing temperature calibrators are usually temperature sensors. FIG. 1 is a schematic diagram of applying temperature sensors on the semiconductor machine for temperature calibration. Referring to FIG. 1, a plurality of temperature sensors 10 are arranged on the semiconductor machine 1. Bottom surfaces of the temperature sensors 10 come into contact with the semiconductor machine 1, while top surfaces and sidewalls thereof are exposed to the air.

Such temperature calibration methods have the following disadvantages. Firstly, since the temperature sensors 10 are large in size and arranged dispersedly, and the sidewalls and top surfaces of the temperature sensors are exposed to the air, the air has a great influence on the measurement of the temperature sensors 10. When a wafer is arranged on the semiconductor machine, only the top surface of the chip on the wafer is exposed to the air, but the sidewall of the chip is not exposed to the air. As a result, the temperature sensors 10 cannot reflect the temperature of the wafer under the same conditions. Secondly, due to the limited number of the temperature sensors 10, the measurement is not comprehensive, only the temperature of some points can be measured, and the temperature distribution of the semiconductor machine cannot be provided.

### SUMMARY

The technical problem to be solved by the present disclosure is to provide a temperature calibration sheet and an application method thereof.

In order to solve the problem mentioned above, the present disclosure provides a temperature calibration sheet, comprising a main body and a plurality of test keys arranged in the main body, the test keys having voltage-temperature characteristic curves corresponding to a set current, temperatures of the test keys being obtained by detecting voltages of the test keys.

Further, the test keys are one of bipolar junction transistors, resistors, and metal-oxide-semiconductor field effect transistors.

Further, an area of the temperature calibration sheet is greater than or equal to an area of a region to be calibrated of a semiconductor machine.

Further, a plurality of exposure units are arranged in the main body, and at least one of the test keys is arranged in each of the exposure units.

Further, the main body is a wafer.

Further, at least one chip is arranged in each of the exposure units, and the test keys are arranged in the chips or on scribe lines between the chips.

Further, on the temperature calibration sheet, the test keys are distributed in such a way that the test keys are in one-to-one or one-to-multiple correspondence to temperature calibration points to be calibrated.

Further, the voltage-temperature characteristic curves are linear function curves.

Further, the test keys are devices of a same type.

The present disclosure further provides an application method for the temperature calibration sheet described above, comprising: placing the temperature calibration sheet on a semiconductor machine, and allowing the temperature calibration sheet to cover a region to be calibrated of the semiconductor machine; energizing test keys on the temperature calibration sheet at an energizing current that is the set current; and, measuring voltages of the test keys corresponding to preset temperature calibration points to obtain temperatures of the test keys, the temperatures being used as temperatures of the temperature calibration points.

Further, a voltage of each of the test keys is measured to obtain a temperature of each of the test keys, and a temperature distribution of the region to be calibrated of the semiconductor machine is obtained.

Further, before the placing the temperature calibration sheet on a semiconductor machine, the application method further comprises: obtaining voltage-temperature characteristic curves of the test keys.

Further, before the placing the temperature calibration sheet on a semiconductor machine, the application method further comprises detecting the temperature calibration sheet: providing a semiconductor machine having a standard temperature; placing the temperature calibration sheet on the semiconductor machine; energizing test keys on the temperature calibration sheet at an energizing current that is the set current; measuring voltages of the test keys to obtain temperatures of the test keys; and, comparing the temperatures of the test keys with the standard temperature of the semiconductor machine, and ending a detection of the temperature calibration sheet if a difference between the temperatures of the test keys and the standard temperature is less than or equal to a set value.

Further, the voltage-temperature characteristic curves of the test keys are obtained again if the difference between the temperatures of the test keys and the standard temperature is greater than the set value.

The present disclosure has the following advantages: the temperature calibration sheet can simulate a state of a wafer, sidewalls of the test keys are not exposed to the air, and the state of the temperature calibration sheet arranged on a semiconductor machine is the same as that of the wafer arranged on the semiconductor machine, such that the temperature of the temperature calibration sheet can truly reflect the temperature of the wafer when arranged on the semiconductor machine, and the temperature of the semiconductor machine can be calibrated accurately.

### BRIEF DESCRIPTION OF THE DRAWINGS

In order to describe the technical solutions in the embodiments of the present disclosure more clearly, the drawings to be used in the embodiments of the present disclosure will be briefly described below. Apparently, the drawings to be used in the following description show only some embodiments of the present disclosure. For a person of ordinary skill in the art, other drawings may be obtained according to these drawings, without paying any creative effort.

FIG. 1 is a schematic diagram of applying existing temperature sensors on a semiconductor machine for temperature calibration;

FIG. 2 is a top view of an embodiment of a temperature calibration sheet according to the present disclosure;

FIG. 3 is a voltage-temperature characteristic curve of a bipolar junction transistor in the temperature calibration sheet according to the present disclosure; and

FIG. 4 is a schematic step diagram of an embodiment of an application method for a temperature calibration sheet according to the present disclosure.

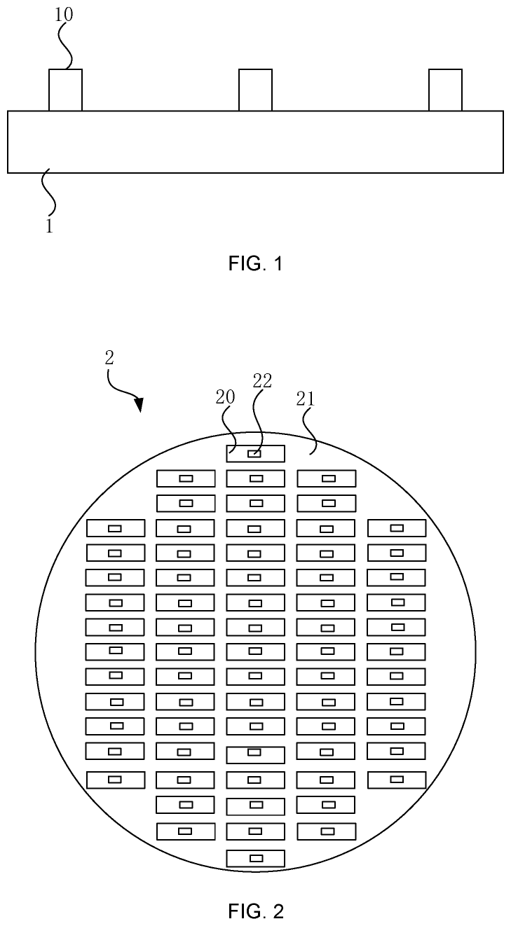

### DETAILED DESCRIPTION

In order to make the objectives, technical means and effects of the present disclosure clearer, the present disclosure will be further explained below with reference to the drawings. It should be understood that the embodiments to be described herein are only some but not all of the embodiments of the present disclosure, and are not intended to limit the present disclosure. All other embodiments obtained on the basis of the embodiments in the present disclosure by those skilled in the art without paying any creative effort shall fall into the protection scope of the present disclosure.

The temperature calibration sheet according to the present disclosure is applicable to scenarios requiring temperature calibration in the semiconductor manufacturing process. In the following embodiments, the description will be given by taking applying the temperature calibration sheet to temperature calibration of a semiconductor machine.

FIG. 2 is a top view of an embodiment of a temperature calibration sheet according to the present disclosure. Referring to FIG. 2, the temperature calibration sheet 2 according to the present disclosure comprises a main body 21 and a plurality of exposure units 20 which are arranged in the main body 21. At least one test key 22 is arranged in each of the exposure units 20. In this embodiment, one test key 22 is arranged in each of the exposure units 20. In other embodiments of the present disclosure, a plurality of test keys 22 may be arranged in each of the exposure units 20. Further, for a same temperature calibration sheet, different numbers of test keys 22 may be arranged in different exposure units 20. For example, according to the temperature calibration requirements, for a region that is sensitive to the change in temperature, a plurality of test keys may be arranged in a same exposure unit to improve the temperature measurement accuracy; however, for a region that is insensitive to the change in temperature, only one test key may be arranged in one exposure unit to save cost.

Further, at least one chip (not shown) is arranged in each of the exposure units, and the test keys 22 may be arranged in the chips or on scribe lines between the chips.

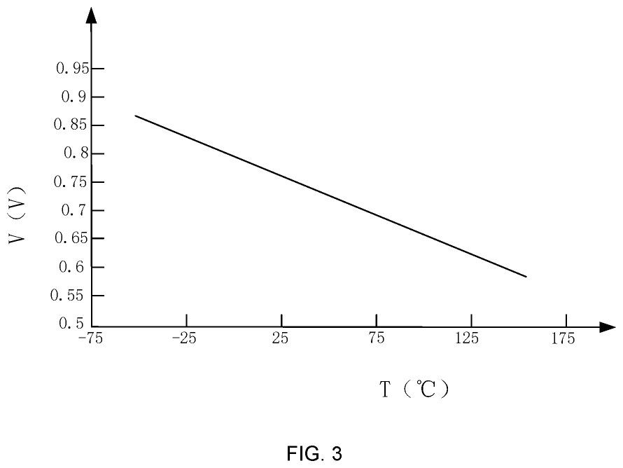

The test keys 22 have voltage-temperature characteristic curves corresponding to a set current. In other words, in a case where the test keys 22 are energized at an energizing current that is the set current, there is a one-to-one function relationship between the voltages and temperatures of the test keys 22. In the present disclosure, any device structures having a voltage-temperature characteristic curve and having a one-to-one relationship between voltage and temperature can be used as the test keys 22. The test keys 22 further comprises, but not limited to, bipolar junction transistors, resistors and metal-oxide-semiconductor (MOS) field effect transistors. For example, when the test keys 22 are bipolar junction transistors, there is a linear function relationship between voltages and temperatures of the test keys 22. FIG. 3 is a voltage-temperature characteristic curve of a bipolar junction transistor. Referring to FIG. 3, the horizontal coordinates are temperatures, the vertical coordinates are voltages, and there is a linear function relationship between voltages and temperatures.

In a case where the voltage-temperature characteristic curves of the test keys 22 at a certain set current are known, the temperatures of the test keys 22 can be obtained by detecting the voltages of the test keys 22. Specifically, the test keys 22 may be energized at an energizing current that is the set current. The voltages of the test keys 22 are measured by a probe or other measurement devices, and corresponding temperatures are obtained from the voltage-temperature characteristic curves by using the measured voltages as known quantities. The temperatures are temperatures of the test keys 22. The temperatures are used as external temperatures at positions corresponding to the test keys 22 (for example, temperatures of the semiconductor machine at positions corresponding to the test keys 22).

Further, different test keys 22 on the same temperature calibration sheet 2 may be devices of a same type or devices of different types. For example, in this embodiment, the test keys 22 on the same temperature calibration sheet 2 are all bipolar junction transistors. However, in another embodiment of the present application, on the same temperature calibration sheet 2, there are bipolar junction transistors as the test keys and metal-oxide-semiconductor field effect transistors as the test keys. When the test keys on the same temperature calibration sheet are devices of a same type, the voltage-temperature characteristic curves of the test keys are approximate, which is convenient for calculation.

It should be understood that the voltage-temperature characteristic curves of the test keys 22 may be different at different set currents. Therefore, before temperature calibration using the temperature calibration sheet, it is usually necessary to determine voltage-temperature characteristic curves at a set current. If the set current is to be changed, it is necessary to determine voltage-temperature characteristic curves corresponding to the new set current again. Further, at a same set current, voltage-temperature characteristic curves of different test keys 22 may be different. Therefore, it is necessary to measure each test key 22 to obtain its voltage-temperature characteristic curve.

Further, in this embodiment, the main body 21 is a wafer having a plurality of exposure units 20. At least one test key 22 is arranged in each of the exposure units 20. Preferably, the test keys 22 are directly manufactured in the wafer. For example, in an embodiment of the present disclosure, if the test keys 22 are resistors, only the resistors are directly manufactured in the wafer by the semiconductor manufacturing process, so as to form the temperature calibration sheet. Alternatively, in another embodiment of the present disclosure, a wafer structure with a chip is prepared by the semiconductor manufacturing process. At least one resistor is arranged around the chip, and the resistors are used as the test keys. The wafer structure may be a wafer structure prepared already.

Since the test keys can be directly manufactured in the wafer to form the temperature calibration sheet during manufacturing the chip in the present disclosure, the temperature calibration sheet can be directly prepared by the semiconductor manufacturing process, without additional semiconductor manufacturing processes, patterns or the like for preparing the calibration temperature sheet, so that the labor, material resource and production cost are saved.

Further, on the temperature calibration sheet, the test keys are distributed in such a way that the test keys are in one-to-one or one-to-multiple correspondence to temperature calibration points to be calibrated. For the semiconductor machine, the temperature calibration points may be positions of chips on a wafer that is to be placed on the semiconductor machine subsequently for manufacturing. Specifically, for the semiconductor machine, the test keys on the temperature calibration sheet are distributed in such a way that the test keys are in one-to-one or one-to-multiple correspondence to the positions of chips on a wafer to be manufactured on the semiconductor machine. For example, one test key on the temperature calibration sheet corresponds to the position of one chip on the wafer, or one test key on the temperature calibration sheet corresponds to the positions of four adjacent chips arranged in a mesh-shaped manner on the wafer. Advantageously, the temperature calibration sheet can further accurately reflect the temperature of each chip of the wafer and improve the measurement accuracy.

Further, the area of the temperature calibration sheet is greater than or equal to that of a region to be calibrated of the semiconductor machine, so that the temperature calibration sheet can realize complete temperature calibration of the semiconductor machine.

As described in the background art, when the semiconductor machines are measured by temperature sensors, sidewalls of the temperature sensors are exposed to the air, and the air will affect the measurement of the temperature sensors, so that the actual temperature of the wafer cannot be reflected and accurate temperature calibration cannot be realized. In accordance with the present disclosure, the temperature calibration sheet can simulate a state of a wafer, sidewalls of the test keys are not exposed to the air, and the state of the temperature calibration sheet arranged on a semiconductor machine is the same as that of the wafer arranged on the semiconductor machine. Therefore, the temperature of the temperature calibration sheet can truly reflect the temperature of the wafer when arranged on the semiconductor machine, and the temperature of the semiconductor machine can be calibrated accurately.

In addition, since the test keys on the temperature calibration sheet according to the present disclosure have a high distribution density, the temperature distribution on the semiconductor machine can be further reflected, thereby providing a reference for the subsequent process.

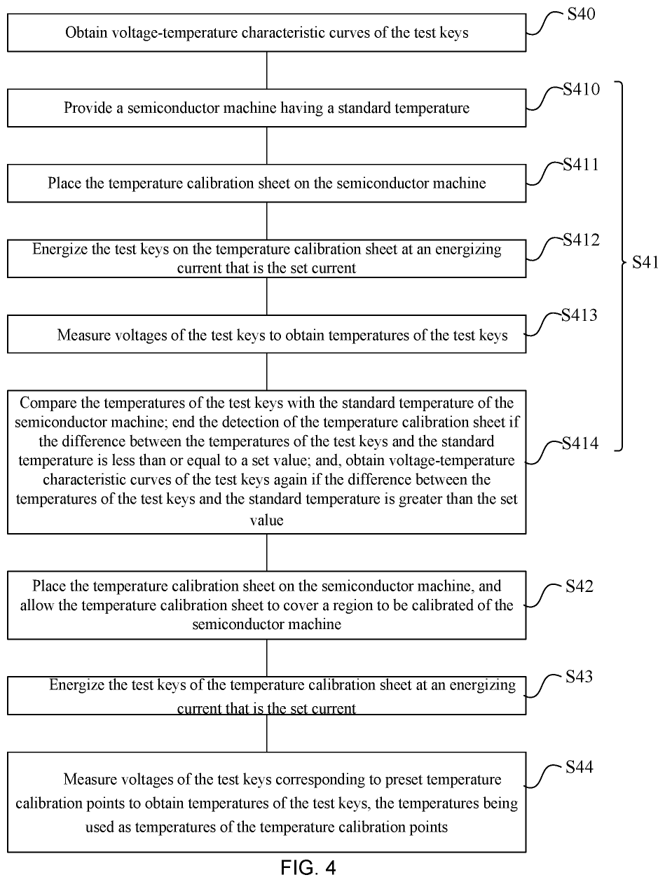

The present disclosure further provides an application method for the temperature calibration sheet described above. FIG. 4 is a schematic step diagram of an embodiment of an application method for a temperature calibration sheet according to the present disclosure. Referring to FIG. 4, the application method comprises.

S40: Voltage-temperature characteristic curves of the test keys are obtained. This step is an optional step.

For the test keys of different types, the method for obtaining the voltage-temperature characteristic curve is different. The voltage-temperature characteristic curves of the test keys may change with the attenuation of the test keys. Therefore, after the temperature calibration sheet is used once or several times, the voltage-temperature characteristic curves of the test keys may be obtained again in reuse, to ensure the accuracy of subsequent temperature calibration.

S41: A step of detecting the temperature calibration sheet is performed. This step is an optional step. This step is performed to detect whether the voltage-temperature characteristic curve of the temperature calibration sheet has changed.

Specifically, this step comprises following steps.

S410: A semiconductor machine having a standard temperature is provided. The semiconductor machine is a machine that is already calibrated. The temperature of each region is known and set as a standard temperature. For example, if a certain region of the semiconductor machine has a temperature of 150° C., 150° C. is set as a standard temperature.

S411: The temperature calibration sheet is placed on the semiconductor machine. That is, the temperature calibration sheet to be used subsequently is placed on the semiconductor machine. In this step, in order to make the temperature of the temperature calibration sheet to be consistent with that of the semiconductor machine, the temperature calibration sheet may be placed on the semiconductor machine for some time.

S412: The test keys on the temperature calibration sheet are energized at an energizing current that is the set current. The set current corresponds to a voltage-temperature characteristic curve.

S413: Voltages of the test keys are measured to obtain temperatures of the test keys. In this step, the voltages of the test keys on the temperature calibration sheet are measured by a probe or other measurement devices, and the temperatures of the test keys corresponding to the voltages are obtained from the voltage-temperature characteristic curves by using the voltages as known parameters.

S414: The temperatures of the test keys are compared with the standard temperature of the semiconductor machine; the detection of the temperature calibration sheet ends if the difference between the temperatures of the test keys and the standard temperature is less than or equal to a set value; and, the voltage-temperature characteristic values of the test keys are obtained again if the difference between the temperatures of the test keys and the standard temperature is greater than the set value. The set value is an allocable error in practice and can be set according to the actual situation. When the difference between the temperatures of the test keys and the standard temperature is less than or equal to the set value, it indicates that the temperature measurement of the test keys of the temperature calibration sheet is within an allowable error range, and the temperature calibration sheet can operate normally; and, when the difference between the temperatures of the test keys and the standard temperature is greater that the set value, it indicates that the temperature measurement of the test keys of the temperature calibration sheet goes beyond the allowable error range, the temperature calibration sheet cannot operate normally, and the step S40 will be executed again.

S42: The temperature calibration sheet is placed on a semiconductor machine, and the temperature calibration sheet covers a region to be calibrated of the semiconductor machine. In this step, the temperature calibration sheet is placed on a semiconductor machine to be calibrated. The temperature calibration sheet can be adhered to the semiconductor machine, and the sidewalls of the test keys are not exposed to the air.

S43: The test keys on the temperature calibration sheet are energized at an energizing current that is the set current. Since the voltage-temperature characteristic curve is known at a set current and unknown at a non-set current, in this step, the channel current is the set current.

S44: Voltages of the test keys corresponding to preset temperature calibration points are measured to obtain temperatures of the test keys, the temperatures being used as temperatures of the temperature calibration points. In this step, according to actual needs, it is possible to measure the voltages of only the test keys corresponding to the preset temperature calibration points, or it is also possible to measure the voltages of all the test keys.

In accordance with the present disclosure, the temperature calibration sheet can cover all regions to be measured of the semiconductor machine, and a plurality of test keys are arranged in the temperature calibration sheet, so any position on the semiconductor machine can be measured, and the maneuverability is high. Preferably, in order to obtain a temperature distribution of a region to be calibrated of the semiconductor machine, the voltage of each test key can be measured to obtain the temperature of each test key, so that a temperature distribution of the region to be calibrated of the semiconductor machine is obtained.

The above description merely shows the preferred implementations of the present disclosure. It should be noted that for a person of ordinary skill in the art, various improvements and modifications may be made without departing from the principle of the present disclosure, and those improvements and modifications shall also be regarded as falling into the protection scope of the present disclosure.

What is claimed is:

1. A temperature calibration sheet, comprising a main body and a plurality of test keys arranged in the main body, the test keys having voltage-temperature characteristic curves corresponding to a set current, temperatures of the test keys being obtained by detecting voltages of the test keys.

2. The temperature calibration sheet according to claim 1, wherein the test keys are one of bipolar junction transistors, resistors, and metal-oxide-semiconductor field effect transistors.

3. The temperature calibration sheet according to claim 1, wherein an area of the temperature calibration sheet is greater than or equal to an area of a region to be calibrated of a semiconductor machine.

4. The temperature calibration sheet according to claim 1, wherein a plurality of exposure units are arranged in the main body, and at least one of the test keys is arranged in each of the exposure units.

5. The temperature calibration sheet according to claim 4, wherein the main body is a wafer.

6. The temperature calibration sheet according to claim 4, wherein at least one chip is arranged in each of the exposure units, and the test keys are arranged in the chips or on scribe lines between the chips.

7. The temperature calibration sheet according to claim 1, wherein, on the temperature calibration sheet, the test keys are distributed in such a way that the test keys are in one-to-one or one-to-multiple correspondence to temperature calibration points to be calibrated.

8. The temperature calibration sheet according to claim 1, wherein the voltage-temperature characteristic curves are linear function curves.

9. The temperature calibration sheet according to claim 1, wherein the test keys are devices of a same type.

10. An application method for a temperature calibration sheet according to claim 1, comprising:
placing the temperature calibration sheet on a semiconductor machine, and allowing the temperature calibration sheet to cover a region to be calibrated of the semiconductor machine;
energizing test keys on the temperature calibration sheet at an energizing current that is the set current; and
measuring voltages of the test keys corresponding to preset temperature calibration points to obtain temperatures of the test keys, the temperatures being used as temperatures of the temperature calibration points.

11. The application method for the temperature calibration sheet according to claim 10, wherein a voltage of each of the test keys is measured to obtain a temperature of each of the test keys, and a temperature distribution of the region to be calibrated of the semiconductor machine is obtained.

12. The application method for the temperature calibration sheet according to claim 10, before the placing the temperature calibration sheet on a semiconductor machine, the application method further comprises:
obtaining voltage-temperature characteristic curves of the test keys.

13. The application method for the temperature calibration sheet according to claim 10, before the placing the temperature calibration sheet on a semiconductor machine, the application method further comprises detecting the temperature calibration sheet:
providing a semiconductor machine having a standard temperature;
placing the temperature calibration sheet on the semiconductor machine;
energizing test keys on the temperature calibration sheet at an energizing current that is the set current;
measuring voltages of the test keys to obtain temperatures of the test keys; and
comparing the temperatures of the test keys with the standard temperature of the semiconductor machine, and ending a detection of the temperature calibration sheet if a difference between the temperatures of the test keys and the standard temperature is less than or equal to a set value.

14. The application method for the temperature calibration sheet according to claim 13, wherein the voltage-temperature characteristic curves of the test keys are obtained again if the difference between the temperatures of the test keys and the standard temperature is greater than the set value.
